(19) United States
(12) Patent Application Publication
(10) Pub. No.: US 2026/0150668 A1
(43) Pub. Date: May 28, 2026

(54) CHIP PACKAGE STRUCTURE WITH HEAT SINK AND METHOD FOR FORMING THE SAME

(71) Applicant: TAIWAN SEMICONDUCTOR MANUFACTURING COMPANY, LTD., Hsinchu (TW)

(72) Inventors: Sing-Da JIANG, Taichung City (TW); Shih-Wei LIU, Chiayi City (TW); Tsun-Yen WU, Hsinchu County (TW); Kathy Wei YAN, Hsinchu (TW)

(73) Assignee: TAIWAN SEMICONDUCTOR MANUFACTURING COMPANY, LTD., Hsinchu (TW)

(21) Appl. No.: 18/956,793

(22) Filed: Nov. 22, 2024

(51) Int. Cl. H01L 23/367; H01L 21/48; H01L 21/56; H01L 23/00; H01L 23/498; H01L 25/065

(52) U.S. Cl. CPC H10W 40/226; H10W 40/037; H10W 70/60; H10W 70/635; H10W 74/016; H10W 90/00; H10W 90/701; H10W 74/15; H10W 90/724; H10W 90/726; H10W 90/734

(57) ABSTRACT

A method for forming a chip package structure is provided. The method includes providing a chip having a semiconductor substrate and a conductive bump. The semiconductor substrate has a front surface and a back surface, and the conductive bump is over the front surface. The method includes partially removing the semiconductor substrate from the back surface to form a recess in the semiconductor substrate. After the semiconductor substrate is partially removed, the semiconductor substrate has a first pillar and a second pillar protruding from a bottom surface of the recess. The method includes bonding a heat sink to the chip. The heat sink has a first channel and a second channel, and the first channel and the second channel pass through the heat sink and connect the recess.

### BACKGROUND

The semiconductor integrated circuit (IC) industry has experienced rapid growth. Technological advances in IC materials and design have produced generations of ICs. Each generation has smaller and more complex circuits than the previous generation. However, these advances have increased the complexity of processing and manufacturing ICs.

In the course of IC evolution, functional density (i.e., the number of interconnected devices per chip area) has generally increased while geometric size (i.e., the smallest component (or line) that can be created using a fabrication process) has decreased. This scaling-down process generally provides benefits by increasing production efficiency and lowering associated costs.

However, since feature sizes continue to decrease, chips generate more heat. Therefore, it is a challenge to form packages with good heat dissipation performance.

### BRIEF DESCRIPTION OF THE DRAWINGS

Aspects of the present disclosure are best understood from the following detailed description when read with the accompanying figures. It should be noted that, in accordance with standard practice in the industry, various features are not drawn to scale. In fact, the dimensions of the various features may be arbitrarily increased or reduced for clarity of discussion.

FIGS. 1A-1I are cross-sectional views of various stages of a process for forming a chip package structure, in accordance with some embodiments.

FIG. 1D-1 is a top view of the chip of FIG. 1D, in accordance with some embodiments.

FIG. 1D-2 is a top view of a pillar of the chip of FIG. 1D, in accordance with some embodiments.

FIG. 1E-1 is a top view of the chip package of FIG. 1E, in accordance with some embodiments.

FIG. 1G-1 is a top view of the chip package of FIG. 1G, in accordance with some embodiments.

FIG. 1H-1 is a top view of the chip package of FIG. 1H, in accordance with some embodiments.

FIG. 1I-1 is a top view of the chip package structure of FIG. 1I, in accordance with some embodiments.

FIG. 1I-2 is a top view of a first region of the chip package structure of FIG. 1I-1, in accordance with some embodiments.

FIG. 1I-3 is a top view of a second region of the chip package structure of FIG. 1I-1, in accordance with some embodiments.

FIG. 2A is a cross-sectional view of a chip package structure, in accordance with some embodiments.

FIG. 2B is a top view of the chip package structure of FIG. 2A, in accordance with some embodiments.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Furthermore, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The term “substantially” in the description, such as in “substantially flat” or in “substantially coplanar”, etc., will be understood by the person skilled in the art. In some embodiments the adjective substantially may be removed. Where applicable, the term “substantially” may also include embodiments with “entirely”, “completely”, “all”, etc. The term “substantially” may be varied in different technologies and be in the deviation range understood by the skilled in the art. For example, the term “substantially” may also relate to 90% of what is specified or higher, such as 95% of what is specified or higher, especially 99% of what is specified or higher, including 100% of what is specified, though the present invention is not limited thereto. Furthermore, terms such as “substantially parallel” or “substantially perpendicular” may be interpreted as not to exclude insignificant deviation from the specified arrangement and may include for example deviations of up to 10°. The word “substantially” does not exclude “completely” e.g. a composition which is “substantially free” from Y may be completely free from Y.

The term “about” may be varied in different technologies and be in the deviation range understood by the skilled in the art. The term “about” in conjunction with a specific distance or size is to be interpreted so as not to exclude insignificant deviation from the specified distance or size. For example, the term “about” may include deviations of up to 10% of what is specified, though the present invention is not limited thereto. The term “about” in relation to a numerical value x may mean x ±5 or 10% of what is specified, though the present invention is not limited thereto.

Some embodiments of the disclosure are described. Additional operations can be provided before, during, and/or after the stages described in these embodiments. Some of the stages that are described can be replaced or eliminated for different embodiments. Additional features can be added to the semiconductor device structure. Some of the features described below can be replaced or eliminated for different embodiments. Although some embodiments are discussed with operations performed in a particular order, these operations may be performed in another logical order.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

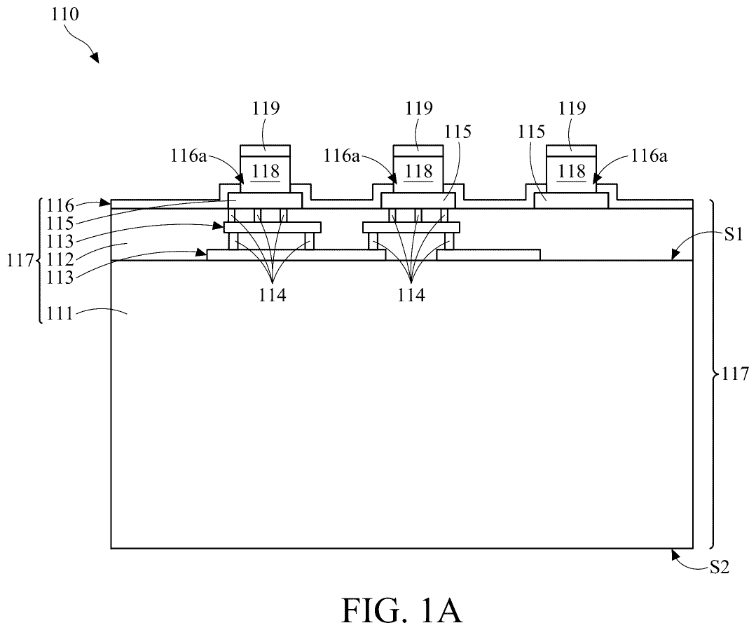

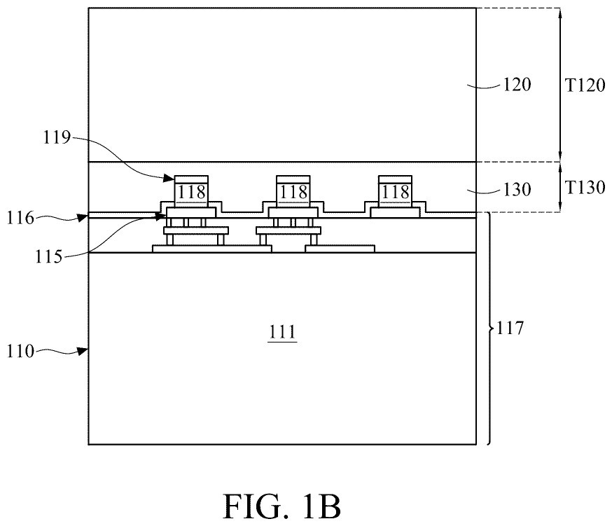

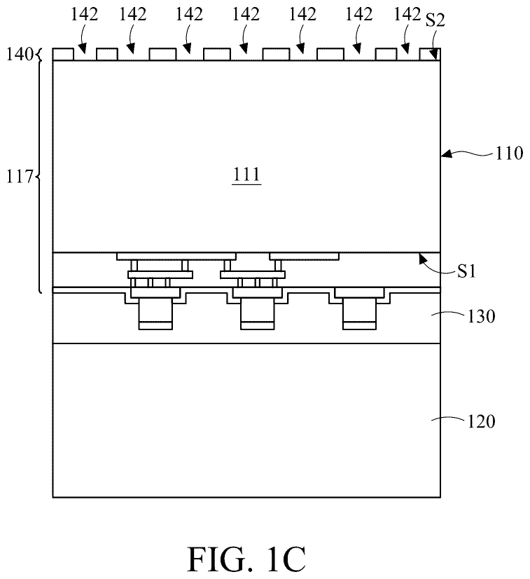

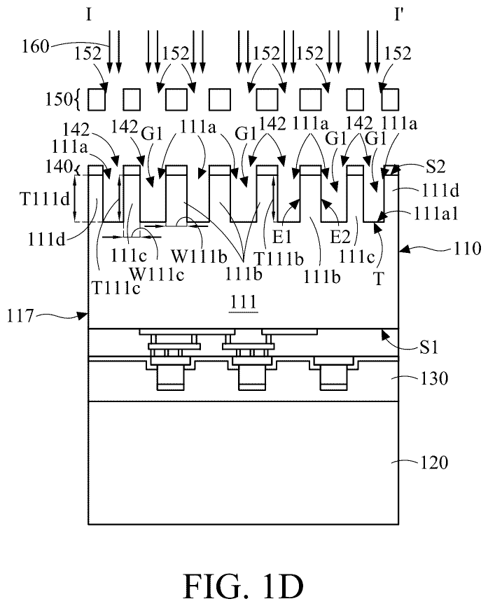

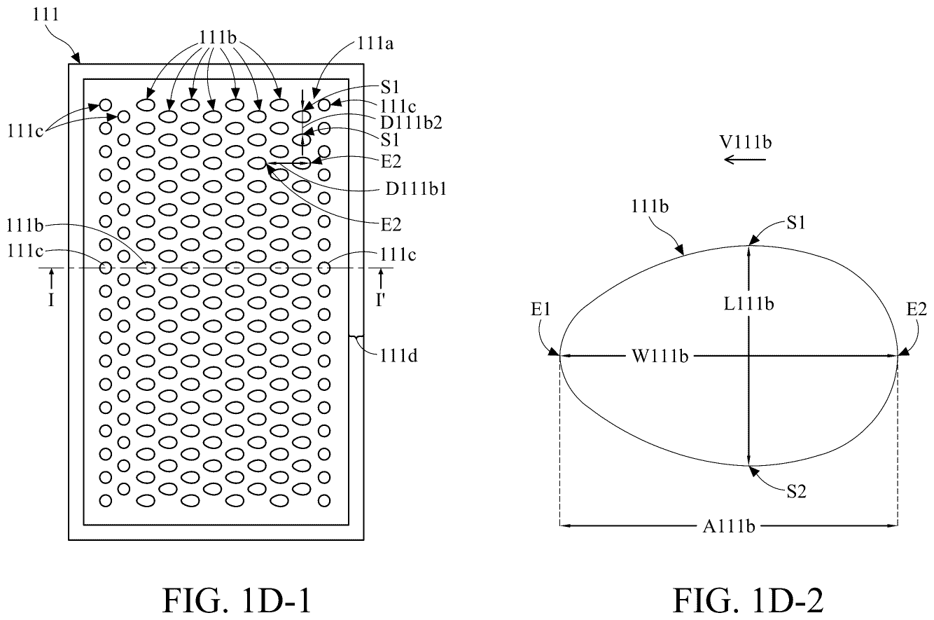

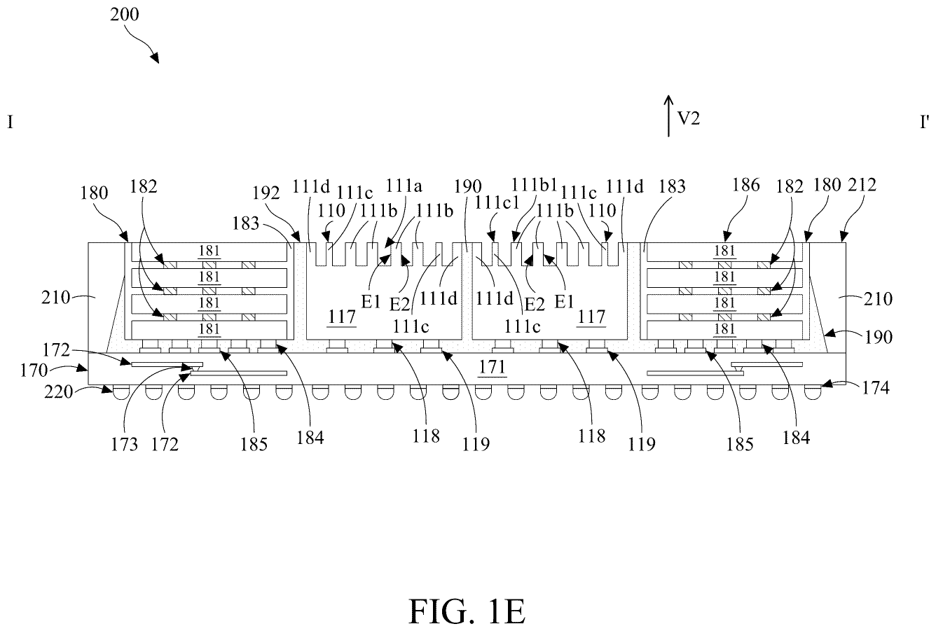

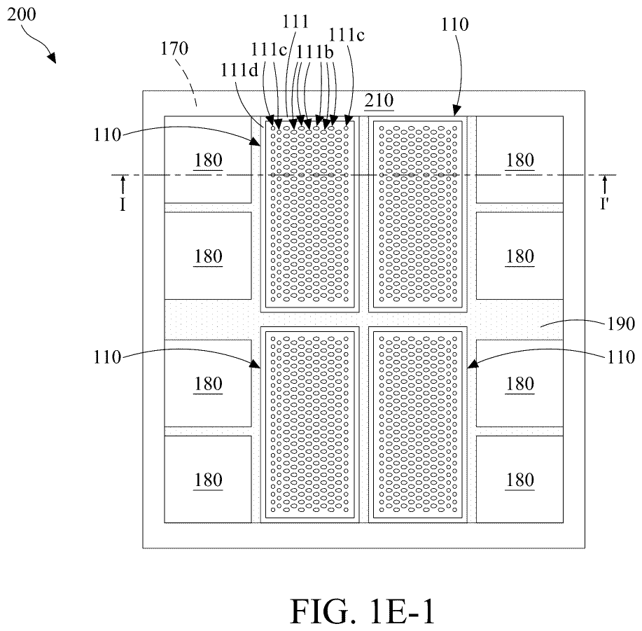

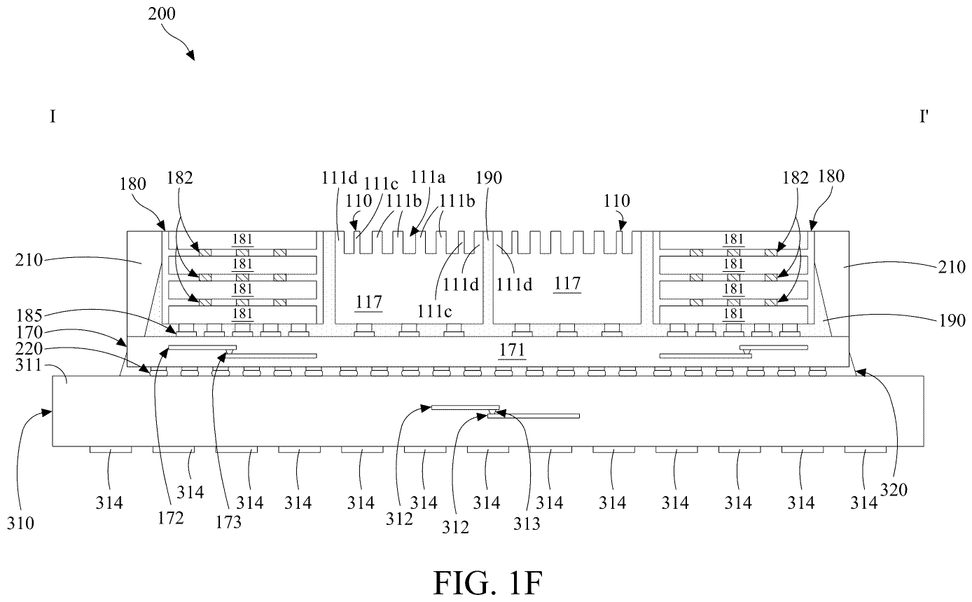

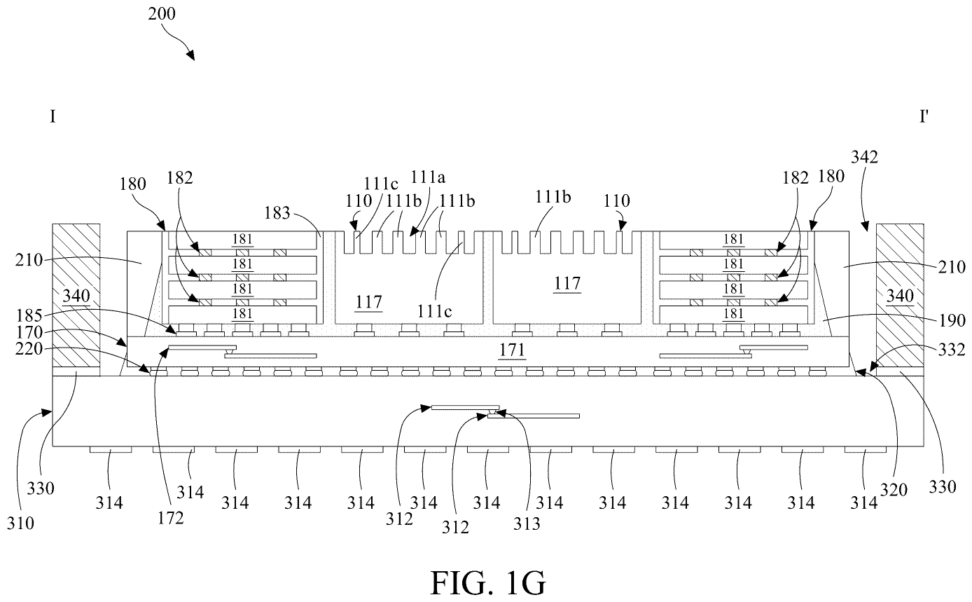

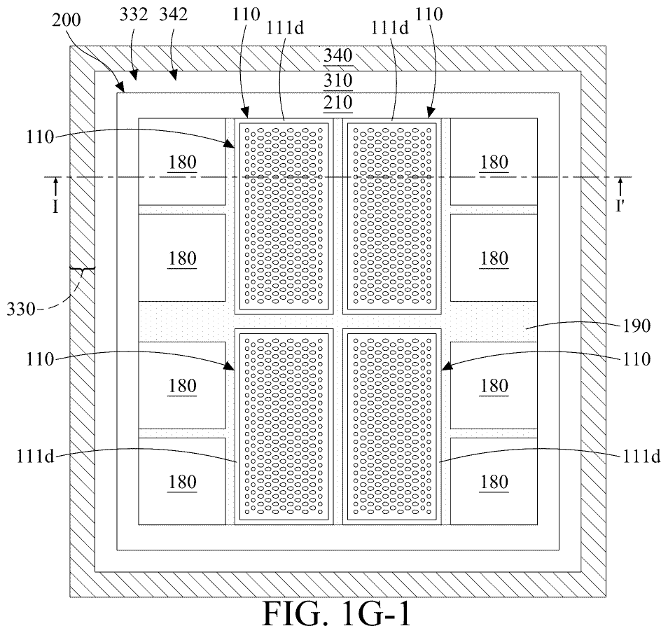

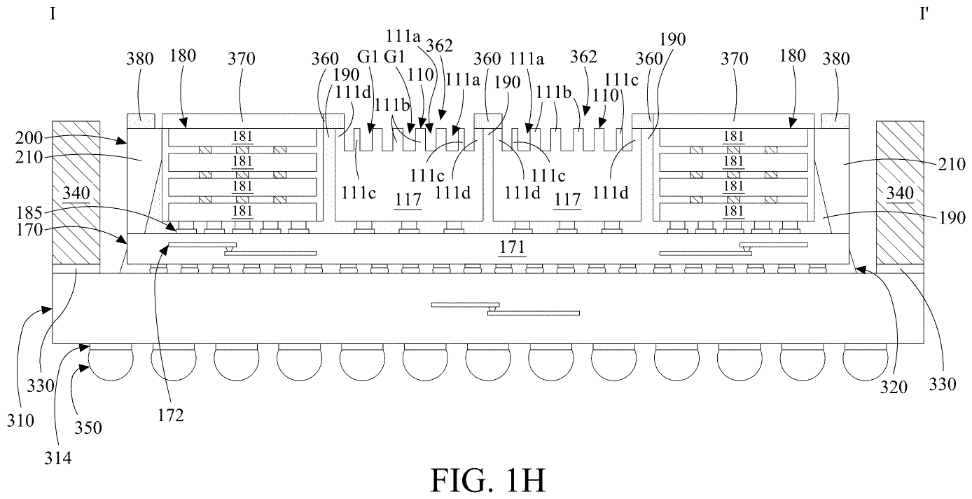

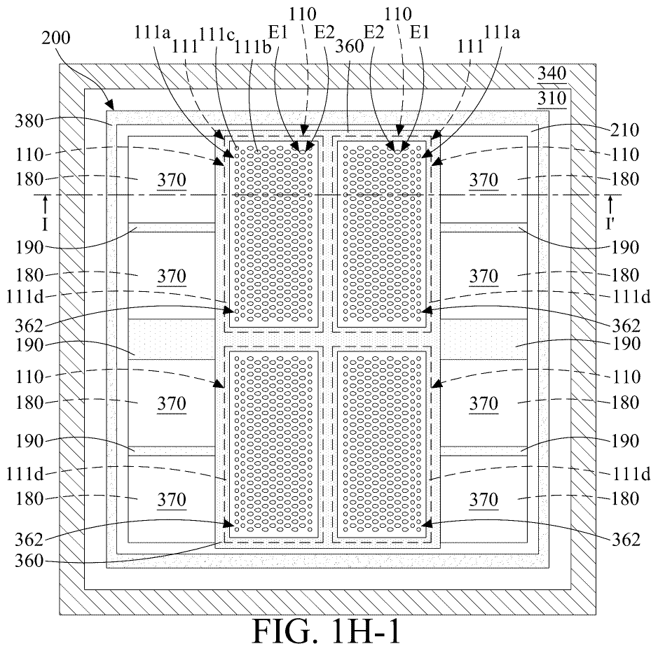

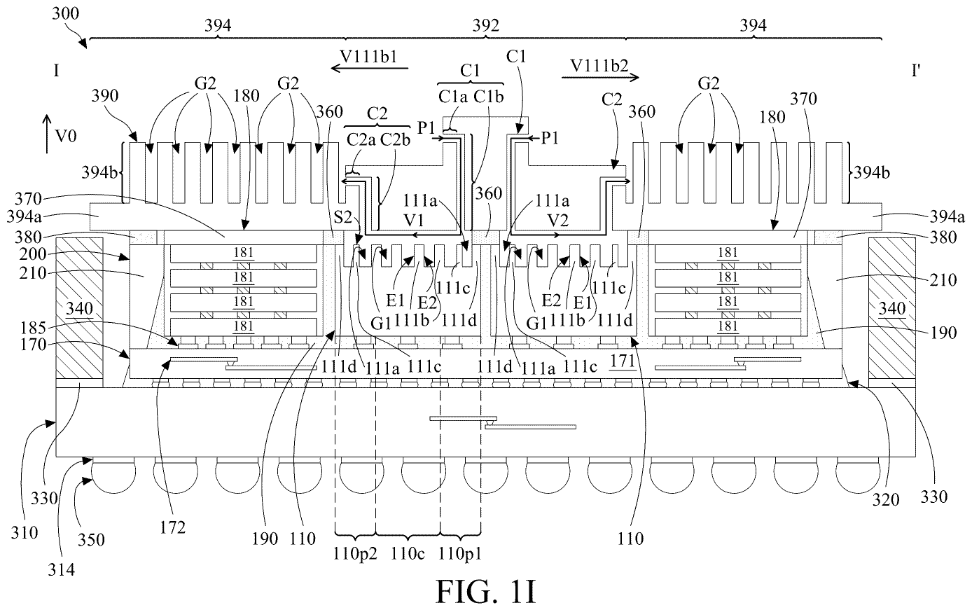

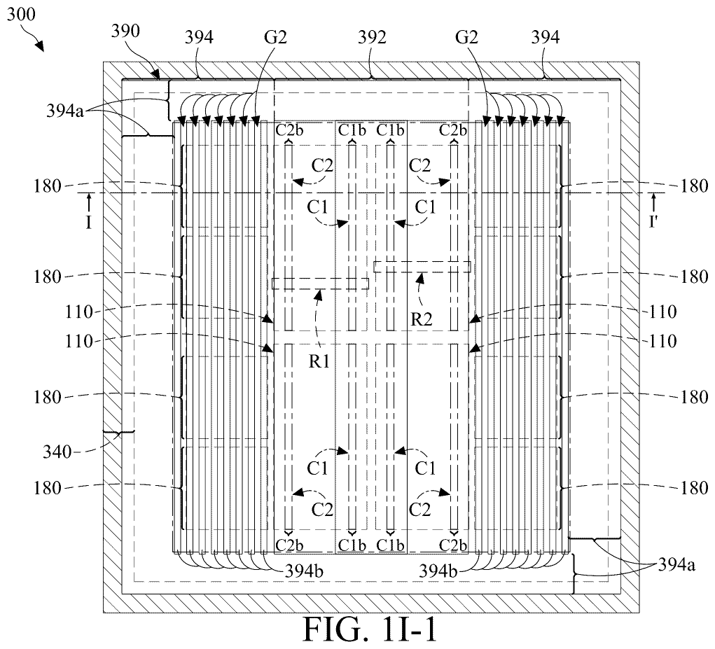

FIGS. 1A-1I are cross-sectional views of various stages of a process for forming a chip package structure, in accordance with some embodiments. As shown in FIG. 1A, a chip 110 is provided, in accordance with some embodiments.

The chip 110 includes a semiconductor substrate 111, a dielectric layer 112, wiring layers 113, conductive vias 114, conductive pads 115, a passivation layer 116, conductive bumps 118, and a solder layer 119, in accordance with some embodiments. The semiconductor substrate 111 has a front surface S1 and a back surface S2, in accordance with some embodiments.

In some embodiments, the semiconductor substrate 111 is made of an elementary semiconductor material including silicon or germanium in a single crystal structure, a polycrystal structure, or an amorphous structure. In some other embodiments, the semiconductor substrate 111 is made of a compound semiconductor, such as silicon carbide, gallium arsenide, gallium phosphide, indium phosphide, indium arsenide, an alloy semiconductor, such as SiGe or GaAsP, or a combination thereof. The semiconductor substrate 111 may also include multi-layer semiconductors, semiconductor on insulator (SOI) (such as silicon on insulator or germanium on insulator), or a combination thereof.

In some embodiments, various devices (not shown) are formed in and/or over the semiconductor substrate 111. Examples of the various devices include active devices, passive devices, other suitable devices, or a combination thereof. The active devices may include transistors or diodes formed at a surface of the semiconductor substrate 111. The passive devices include resistors, capacitors, or other suitable passive devices.

For example, the transistors may be metal oxide semiconductor field effect transistors (MOSFET), complementary metal oxide semiconductor (CMOS) transistors, bipolar junction transistors (BJT), high-voltage transistors, high-frequency transistors, p-channel and/or n-channel field effect transistors (PFETs/NFETs), etc.

Various processes, such as front-end-of-line (FEOL) semiconductor fabrication processes, are performed to form the various devices. The FEOL semiconductor fabrication processes may include deposition, etching, implantation, photolithography, annealing, planarization, one or more other applicable processes, or a combination thereof.

In some embodiments, isolation features (not shown) are formed in the semiconductor substrate 111. The isolation features are used to surround active regions and electrically isolate various devices formed in and/or over the semiconductor substrate 111 in the active regions. In some embodiments, the isolation features include shallow trench isolation (STI) features, local oxidation of silicon (LOCOS) features, other suitable isolation features, or a combination thereof.

As shown in FIG. 1A, the dielectric layer 112 is formed over the front surface S1 of the semiconductor substrate 111, in accordance with some embodiments. The wiring layers 113 and the conductive vias 114 are formed in the dielectric layer 112, in accordance with some embodiments. The conductive pads 115 are formed over the dielectric layer 112, in accordance with some embodiments.

The conductive vias 114 are electrically connected between different wiring layers 113, in accordance with some embodiments. The conductive vias 114 are electrically connected between the wiring layer 113 and the conductive pads 115, in accordance with some embodiments. The conductive vias 114 are electrically connected between the wiring layer 113 and the devices (which are formed in and/or over the semiconductor substrate 111), in accordance with some embodiments.

The dielectric layer 112 is made of a dielectric material, such as silicon oxide, silicon nitride, un-doped silicate glass (USG), or another suitable material, in accordance with some embodiments. The wiring layers 113 are made of a conductive material, such as metal (e.g., aluminum, copper, silver, gold, nickel, or tungsten) or alloys thereof, in accordance with some embodiments.

The conductive vias 114 are made of a conductive material, such as metal (e.g., aluminum, copper, silver, gold, nickel, or tungsten) or alloys thereof, in accordance with some embodiments. The conductive pads 115 are made of a conductive material, such as metal (e.g., aluminum, copper, silver, gold, nickel, or tungsten) or alloys thereof, in accordance with some embodiments.

As shown in FIG. 1A, the passivation layer 116 is formed over the dielectric layer 112 to cover edge portions of the conductive pads 115, in accordance with some embodiments. The passivation layer 116 has openings 116a partially exposing the conductive pads 115, in accordance with some embodiments.

The passivation layer 116 is made of a dielectric material, such as polyimide, silicon oxide, silicon nitride, un-doped silicate glass (USG), or another suitable material, in accordance with some embodiments. In some embodiments, the semiconductor substrate 111, the dielectric layer 112, the wiring layers 113, the conductive vias 114, the conductive pads 115, and the passivation layer 116 together form a chip structure 117.

The conductive bumps 118 are formed over the conductive pads 115 respectively, in accordance with some embodiments. In some embodiments, the conductive bumps 118 are made of a conductive material such as copper (Cu), an alloy thereof, or the combination thereof, in accordance with some embodiments. The conductive bumps 118 are formed using a plating process such as an electroplating process, in accordance with some embodiments.

The solder layer 119 is formed over the conductive bumps 118, in accordance with some embodiments. The solder layer 119 is made of tin (Sn), the like, alloys thereof, or another suitable conductive material with a melting point lower than that of the conductive bumps 118, in accordance with some embodiments. The solder layer 119 is formed using a plating process such as an electroplating process, in accordance with some embodiments.

As shown in FIG. 1B, a carrier substrate 120 is bonded to the chip 110 through a glue layer 130, in accordance with some embodiments. The thickness T120 of the carrier substrate 120 ranges from about 400 μm to about 600 μm, in accordance with some embodiments.

The thickness T130 of the glue layer 130 ranges from about 40 μm to about 80 μm, in accordance with some embodiments. The carrier substrate 120 is made of a rigid material such as a glass material, in accordance with some embodiments. The glue layer 130 is made of an adhesive material such as a polymer material, in accordance with some embodiments.

As shown in FIG. 1C, the chip 110 is flipped upside down, in accordance with some embodiments. As shown in FIG. 1C, a mask layer 140 is formed over the back surface S2 of the semiconductor substrate 111, in accordance with some embodiments. The mask layer 140 has openings 142, in accordance with some embodiments. The openings 142 expose portions of the semiconductor substrate 111, in accordance with some embodiments.

As shown in FIG. 1D, an etching mask 150 is disposed over the chip 110, in accordance with some embodiments. The etching mask 150 has openings 152, in accordance with some embodiments. The openings 152 are aligned with the openings 142 of the mask layer 140 respectively, in accordance with some embodiments.

As shown in FIG. 1D, an anisotropic etching process 160 is performed to remove the portions of the semiconductor substrate 111 from the back surface S2 through the openings 142, in accordance with some embodiments. As shown in FIG. 1D, a recess 111a is formed in the semiconductor substrate 111 and under the openings 142 after the anisotropic etching process 160 is performed, in accordance with some embodiments. The anisotropic etching process 160 includes a plasma etching process, in accordance with some embodiments.

FIG. 1D-1 is a top view of the semiconductor substrate 111 of the chip 110 of FIG. 1D, in accordance with some embodiments. As shown in FIGS. 1D and 1D-1, after the anisotropic etching process 160 is performed, the semiconductor substrate 111 has pillars 111b and 111c and a peripheral ring portion 111d, in accordance with some embodiments.

The peripheral ring portion 111d surrounds the recess 111a, in accordance with some embodiments. The recess 111a has a bottom surface 111a1, in accordance with some embodiments. The pillars 111b and 111c protrude from the bottom surface 111a1 of the recess 111a, in accordance with some embodiments. The pillars 111b and 111c and the peripheral ring portion 111d are spaced apart from each other by gaps G1, in accordance with some embodiments.

The thickness T111b of the pillar 111b ranges from about 180 μm to about 280 μm, in accordance with some embodiments. The thickness T111c of the pillar 111c ranges from about 180 μm to about 280 μm, in accordance with some embodiments. The thickness T111d of the peripheral ring portion 111d ranges from about 180 μm to about 280 μm, in accordance with some embodiments.

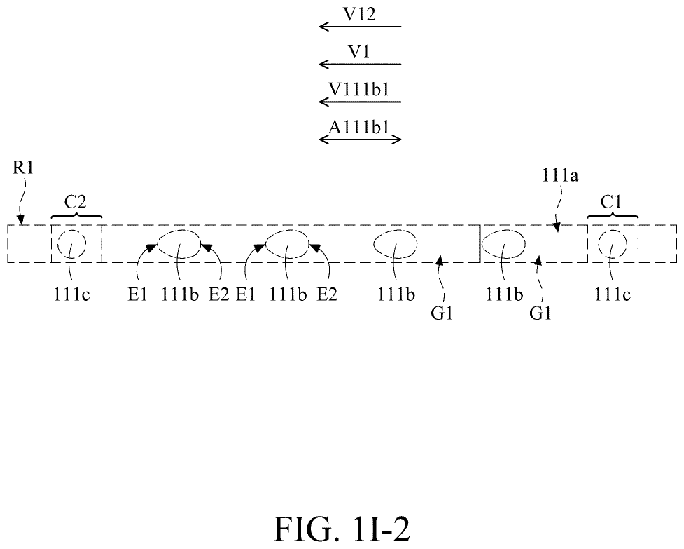

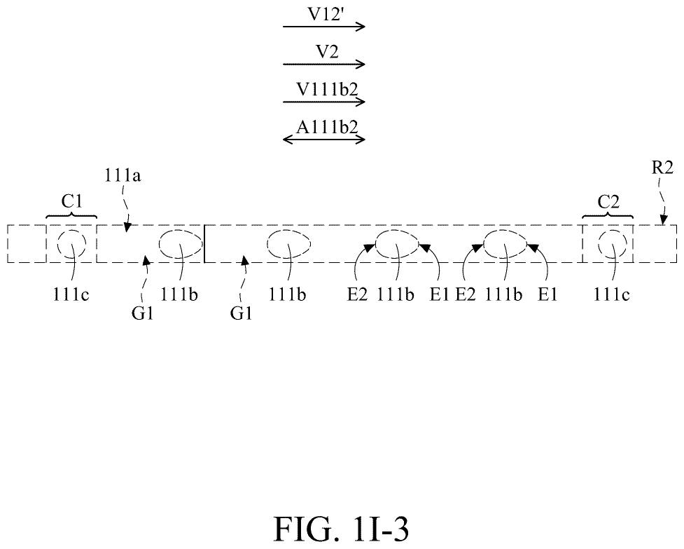

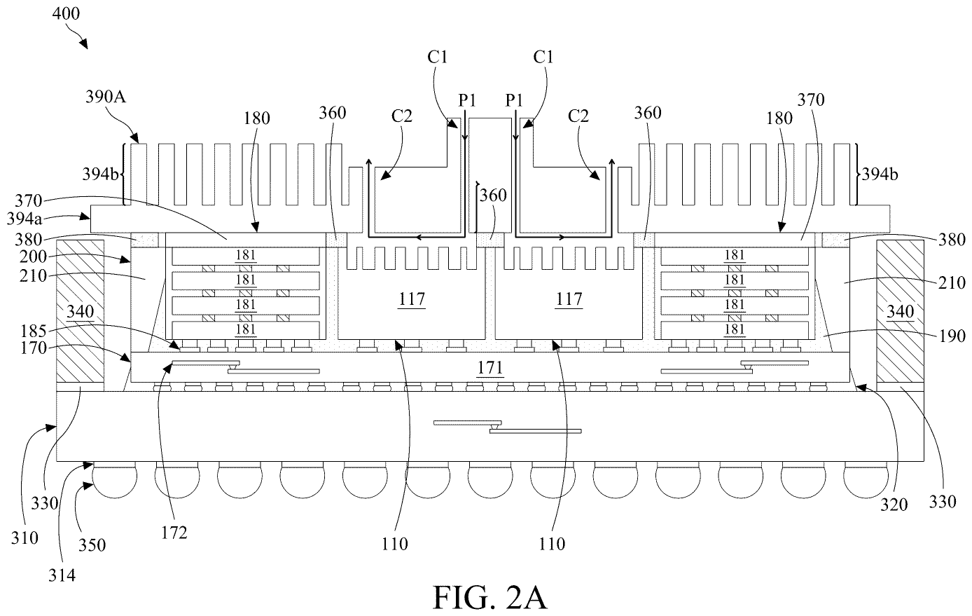

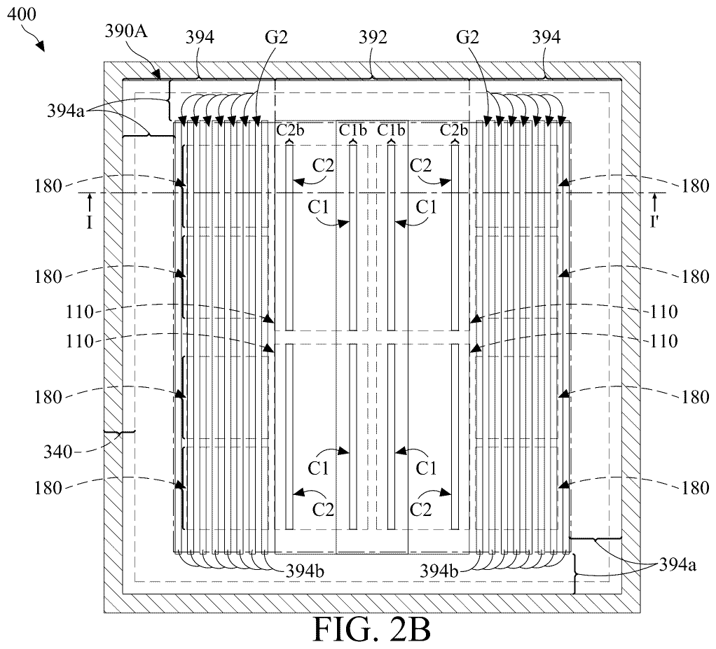

As shown in FIG. 1D-1, the pillar 111c has a round shape, in accordance with some embodiments. FIG. 1D-2 is a top view of the pillar 111b of the semiconductor substrate 111 of the chip 110 of FIG. 1D, in accordance with some embodiments. As shown in FIGS. 1D-1 and 1D-2, the pillar 111b has an egg-like shape, in accordance with some embodiments.

Since the pillars 111c and 111b have hydrodynamic friendly design (e.g., a round shape or an egg-like shape), this design can reduce the flow resistance of the cooling liquid flowing in the recess 111a of the semiconductor substrate 111 of the chip 110, thereby increasing the flow rate and heat dissipation efficiency of the cooling liquid, and reducing the power consumption of the pump that provides the cooling liquid, in accordance with some embodiments.

As shown in FIG. 1D-2, the pillar 111b has a narrow rounded end E1 and a wide rounded end E2, in accordance with some embodiments. The narrow rounded end E1 is opposite to the wide rounded end E2, in accordance with some embodiments. The width W111b of the pillar 111b is equal to the distance between the narrow rounded end E1 and the wide rounded end E2, in accordance with some embodiments.

The width W111b of the pillar 111b ranges from about 300 μm to about 400 μm, in accordance with some embodiments. As shown in FIGS. 1D-1 and 1D-2, the distance D111b1 between the wide rounded ends E2 of two adjacent pillars 111b ranges from about 800 μm to about 1000 μm, in accordance with some embodiments.

As shown in FIG. 1D-2, the pillar 111b has curved sidewalls S1 and S2, in accordance with some embodiments. The curved sidewall S1 is opposite to the curved sidewall S2, in accordance with some embodiments. The curved sidewall S1 is connected between the narrow rounded end E1 and the wide rounded end E2, in accordance with some embodiments. The curved sidewall S2 is connected between the narrow rounded end E1 and the wide rounded end E2, in accordance with some embodiments.

The length L111b of the pillar 111b is equal to the distance between the curved sidewalls S1 and S2, in accordance with some embodiments. The length L111b of the pillar 111b ranges from about 170 μm to about 270 μm, in accordance with some embodiments. As shown in FIGS. 1D-1 and 1D-2, the distance D111b2 between the curved sidewalls S1 of two adjacent pillars 111b ranges from about 400 μm to about 600 μm, in accordance with some embodiments.

As shown in FIG. 1D-2, the pillar 111b has a major axis A111b between the narrow rounded end E1 and the wide rounded end E2, in accordance with some embodiments. The major axis A111b is parallel to a flow direction of the cooling liquid flowing in the recess 111a of the semiconductor substrate 111 of the chip 110 in the subsequent process, in accordance with some embodiments.

In some embodiments, a direction V111b from the wide rounded end E2 to the narrow rounded end E1 is parallel to the flow direction of the cooling liquid flowing in the recess 111a of the semiconductor substrate 111 of the chip 110 in the subsequent process, which can reduce the flow resistance of the cooling liquid flowing in the recess 111a. As shown in FIG. 1D, the width W111b of the pillar 111b is greater than the width W111c of the pillar 111c, in accordance with some embodiments.

As shown in FIG. 1E, the mask layer 140 is removed, in accordance with some embodiments. As shown in FIG. 1E, the carrier substrate 120 and the glue layer 130 is removed, in accordance with some embodiments. FIG. 1E-1 is a top view of the chip package of FIG. 1E, in accordance with some embodiments.

As shown in FIGS. 1E and 1E-1, the chips 110 are bonded to a redistribution substrate 170, in accordance with some embodiments. The pillars 111b and 111c extend in a direction V0 away from the redistribution substrate 170, in accordance with some embodiments.

The redistribution substrate 170 includes a dielectric layer 171, wiring layers 172, conductive vias 173, and conductive pads 174, in accordance with some embodiments. The wiring layers 172 and the conductive vias 173 are formed in the dielectric layer 171, in accordance with some embodiments. The conductive pads 174 are formed under the dielectric layer 171, in accordance with some embodiments.

The conductive vias 173 are electrically connected between different wiring layers 172, in accordance with some embodiments. The conductive vias 173 are electrically connected between the wiring layer 172 and the conductive pads 174, in accordance with some embodiments.

The dielectric layer 171 is made of a dielectric material, such as silicon oxide, silicon nitride, un-doped silicate glass (USG), or another suitable material, in accordance with some embodiments. The wiring layers 172 are made of a conductive material, such as metal (e.g., aluminum, copper, silver, gold, nickel, or tungsten) or alloys thereof, in accordance with some embodiments.

The conductive vias 173 are made of a conductive material, such as metal (e.g., aluminum, copper, silver, gold, nickel, or tungsten) or alloys thereof, in accordance with some embodiments. The conductive pads 174 are made of a conductive material, such as metal (e.g., aluminum, copper, silver, gold, nickel, or tungsten) or alloys thereof, in accordance with some embodiments.

As shown in FIGS. 1E and 1E-1, chip packages 180 are bonded to the redistribution substrate 170, in accordance with some embodiments. The chip packages 180 are also referred to as high bandwidth memory (HBM) packages, in accordance with some embodiments. Each chip package 180 includes chips 181, conductive bumps 182, a molding layer 183, conductive bumps 184, and a solder layer 185, in accordance with some embodiments. The chip 181 is similar to the chip 110, in accordance with some embodiments.

Each chip 181 includes a semiconductor substrate, a dielectric layer, wiring layers, conductive vias, and conductive pads, in accordance with some embodiments. The semiconductor substrate has a front surface and a back surface, in accordance with some embodiments.

In some embodiments, the semiconductor substrate is made of an elementary semiconductor material including silicon or germanium in a single crystal structure, a polycrystal structure, or an amorphous structure. In some other embodiments, the semiconductor substrate is made of a compound semiconductor, such as silicon carbide, gallium arsenide, gallium phosphide, indium phosphide, indium arsenide, an alloy semiconductor, such as SiGe or GaAsP, or a combination thereof. The semiconductor substrate may also include multi-layer semiconductors, semiconductor on insulator (SOI) (such as silicon on insulator or germanium on insulator), or a combination thereof.

In some embodiments, various devices are formed in and/or over the semiconductor substrate. Examples of the various devices include active devices, passive devices, other suitable devices, or a combination thereof. The active devices may include transistors or diodes formed at a surface of the semiconductor substrate. The passive devices include resistors, capacitors, or other suitable passive devices.

For example, the transistors may be metal oxide semiconductor field effect transistors (MOSFET), complementary metal oxide semiconductor (CMOS) transistors, bipolar junction transistors (BJT), high-voltage transistors, high-frequency transistors, p-channel and/or n-channel field effect transistors (PFETs/NFETs), etc.

Various processes, such as front-end-of-line (FEOL) semiconductor fabrication processes, are performed to form the various devices. The FEOL semiconductor fabrication processes may include deposition, etching, implantation, photolithography, annealing, planarization, one or more other applicable processes, or a combination thereof.

In some embodiments, isolation features are formed in the semiconductor substrate. The isolation features are used to surround active regions and electrically isolate various devices formed in and/or over the semiconductor substrate in the active regions. In some embodiments, the isolation features include shallow trench isolation (STI) features, local oxidation of silicon (LOCOS) features, other suitable isolation features, or a combination thereof.

The dielectric layer is formed over the front surface of the semiconductor substrate, in accordance with some embodiments. The wiring layers and the conductive vias are formed in the dielectric layer, in accordance with some embodiments. The conductive pads are formed over the dielectric layer, in accordance with some embodiments.

The conductive vias are electrically connected between different wiring layers, in accordance with some embodiments. The conductive vias are electrically connected between the wiring layer and the conductive pads, in accordance with some embodiments. The conductive vias are electrically connected between the wiring layer and the devices (which are formed in and/or over the semiconductor substrate), in accordance with some embodiments.

The dielectric layer is made of a dielectric material, such as silicon oxide, silicon nitride, un-doped silicate glass (USG), or another suitable material, in accordance with some embodiments. The wiring layers are made of a conductive material, such as metal (e.g., aluminum, copper, silver, gold, nickel, or tungsten) or alloys thereof, in accordance with some embodiments.

The conductive vias are made of a conductive material, such as metal (e.g., aluminum, copper, silver, gold, nickel, or tungsten) or alloys thereof, in accordance with some embodiments. The conductive pads are made of a conductive material, such as metal (e.g., aluminum, copper, silver, gold, nickel, or tungsten) or alloys thereof, in accordance with some embodiments.

The chips 181 are bonded to each other through the conductive bumps 182 therebetween, in accordance with some embodiments. The chips 181 are electrically connected to each other through the conductive bumps 182 therebetween, in accordance with some embodiments. The conductive bumps 182 are made of tin (Sn), the like, alloys thereof, or another suitable conductive material, in accordance with some embodiments.

The molding layer 183 surrounds the chips 181 and the conductive bumps 182, in accordance with some embodiments. The molding layer 183 includes a polymer material or another suitable insulating material, in accordance with some embodiments. The polymer material includes thermosetting polymers, thermoplastic polymers, or mixtures thereof.

The polymer material includes, for example, plastic materials, epoxy resin, polyimide, polyethylene terephthalate (PET), polyvinyl chloride (PVC), polymethylmethacrylate (PMMA), polymer components doped with fillers including fiber, clay, silica, glass, ceramic, inorganic particles, or combinations thereof, in accordance with some embodiments.

The conductive bumps 184 are formed under the bottommost chip 181, in accordance with some embodiments. In some embodiments, the conductive bumps 184 are made of a conductive material such as copper (Cu), an alloy thereof, or the combination thereof, in accordance with some embodiments. The conductive bumps 184 are formed using a plating process such as an electroplating process, in accordance with some embodiments.

The solder layer 185 is formed under the conductive bumps 184, in accordance with some embodiments. The solder layer 185 is bonded to the redistribution substrate 170, in accordance with some embodiments. The solder layer 185 is made of tin (Sn), the like, alloys thereof, or another suitable conductive material with a melting point lower than that of the conductive bumps 184, in accordance with some embodiments. The solder layer 185 is formed using a plating process such as an electroplating process, in accordance with some embodiments.

As shown in FIGS. 1E and 1E-1, an underfill layer 190 is formed over the redistribution substrate 170 to surround the chips 110 and the chip packages 180, in accordance with some embodiments. The underfill layer 190 is formed between the chips 110, the chip packages 180, and the redistribution substrate 170, in accordance with some embodiments. The underfill layer 190 is made of an insulating material, such as a polymer material, in accordance with some embodiments.

As shown in FIGS. 1E and 1E-1, a molding layer 210 is formed over the redistribution substrate 170 to surround the chips 110, the chip packages 180, and the underfill layer 190, in accordance with some embodiments. The top surface 111b1 of the pillar 111b, the top surface 111c1 of the pillar 111c, the top surface 186 of the chip package 180, the top surface 192 of the underfill layer 190, and the top surface 212 of the molding layer 210 are substantially level with each other, in accordance with some embodiments.

The molding layer 210 includes a polymer material or another suitable insulating material, in accordance with some embodiments. The polymer material includes thermosetting polymers, thermoplastic polymers, or mixtures thereof.

The polymer material includes, for example, plastic materials, epoxy resin, polyimide, polyethylene terephthalate (PET), polyvinyl chloride (PVC), polymethylmethacrylate (PMMA), polymer components doped with fillers including fiber, clay, silica, glass, ceramic, inorganic particles, or combinations thereof, in accordance with some embodiments.

As shown in FIG. 1E, conductive bumps 220 are formed over the conductive pads 174, in accordance with some embodiments. The conductive bumps 220 are made of tin (Sn), the like, alloys thereof, or another suitable conductive material, in accordance with some embodiments.

The chips 110, the chip packages 180, the redistribution substrate 170, the underfill layer 190, the molding layer 210, and the conductive bumps 220 together form a chip package 200, in accordance with some embodiments.

As shown in FIG. 1F, the chip package 200 is bonded to a wiring substrate 310 through the conductive bumps 220, in accordance with some embodiments. The wiring substrate 310 includes a dielectric layer 311, wiring layers 312, conductive vias 313, and conductive pads 314, in accordance with some embodiments. The wiring layers 312 and the conductive vias 313 are formed in the dielectric layer 311, in accordance with some embodiments. The conductive pads 314 are formed under the dielectric layer 311, in accordance with some embodiments.

The conductive vias 313 are electrically connected between different wiring layers 312, in accordance with some embodiments. The conductive vias 313 are electrically connected between the wiring layer 312 and the conductive pads 314, in accordance with some embodiments.

The dielectric layer 311 is made of a dielectric material, such as silicon oxide, silicon nitride, un-doped silicate glass (USG), or another suitable material, in accordance with some embodiments. The wiring layers 312 are made of a conductive material, such as metal (e.g., aluminum, copper, silver, gold, nickel, or tungsten) or alloys thereof, in accordance with some embodiments.

The conductive vias 313 are made of a conductive material, such as metal (e.g., aluminum, copper, silver, gold, nickel, or tungsten) or alloys thereof, in accordance with some embodiments. The conductive pads 314 are made of a conductive material, such as metal (e.g., aluminum, copper, silver, gold, nickel, or tungsten) or alloys thereof, in accordance with some embodiments.

As shown in FIG. 1F, an underfill layer 320 is formed between the redistribution substrate 170 and the wiring substrate 310, in accordance with some embodiments. The underfill layer 320 surrounds the redistribution substrate 170 and the conductive bumps 220, in accordance with some embodiments. The underfill layer 320 is made of an insulating material, such as a polymer material, in accordance with some embodiments.

FIG. 1G-1 is a top view of the chip package of FIG. 1G, in accordance with some embodiments. As shown in FIGS. 1G and 1G-1, an adhesive layer 330 is formed over the wiring substrate 310, in accordance with some embodiments. The adhesive layer 330 has an opening 332, in accordance with some embodiments.

The chip package 200 is in the opening 332, in accordance with some embodiments. The adhesive layer 330 surrounds the chip package 200, in accordance with some embodiments. The adhesive layer 330 is made of a polymer material or the like, in accordance with some embodiments.

As shown in FIGS. 1G and 1G-1, a ring structure 340 is bonded to the wiring substrate 310 through the adhesive layer 330, in accordance with some embodiments. The ring structure 340 is also referred to as an anti-warping ring structure, in accordance with some embodiments. The ring structure 340 is harder than the wiring substrate 310, thereby reducing the warpage of the wiring substrate 310, in accordance with some embodiments.

The ring structure 340 has an opening 342 over the opening 332 of the adhesive layer 330, in accordance with some embodiments. The chip package 200 is in the opening 342, in accordance with some embodiments. The ring structure 340 surrounds the chip package 200, in accordance with some embodiments. The ring structure 340 is made of a metal material or alloys thereof, in accordance with some embodiments.

FIG. 1H-1 is a top view of the chip package of FIG. 1H, in accordance with some embodiments. For the sake of simplicity, FIG. 1H-1 does not show the underfill layer 320 of FIG. 1H, in accordance with some embodiments.

As shown in FIGS. 1H and 1H-1, solder balls 350 are formed under the conductive pads 314 of the wiring substrate 310, in accordance with some embodiments. The solder balls 350 are made of tin (Sn), the like, alloys thereof, or another suitable conductive material, in accordance with some embodiments.

As shown in FIGS. 1H and 1H-1, a sealant 360 is formed over the peripheral ring portions 111d of the semiconductor substrates 111 and the underfill layer 190 between the chips 110 and the chip packages 180, in accordance with some embodiments. The sealant 360 has openings 362, in accordance with some embodiments.

The openings 362 expose central portions of the semiconductor substrates 111 respectively, in accordance with some embodiments. The sealant 360 surrounds the pillars 111b and 111c of the semiconductor substrates 111, in accordance with some embodiments. The sealant 360 is made of a polymer material, in accordance with some embodiments.

As shown in FIGS. 1H and 1H-1, a heat conductive layer 370 is formed over the chip packages 180, in accordance with some embodiments. The heat conductive layer 370 is made of a heat conductive material such as indium (In), tin (Sn), or an appropriate material with a good thermal conductivity and thermal diffusivity, in accordance with some embodiments.

The material of the heat conductive layer 370 has a thermal conductivity greater than or equal to 50 W/(m·K), in accordance with some embodiments. The thermal conductivity of the material of the heat conductive layer 370 is greater than that of the sealant 360, the chip package 180, the underfill layer 190, and the molding layer 210, in accordance with some embodiments.

As shown in FIGS. 1H and 1H-1, a ring layer 380 is formed over the molding layer 210, in accordance with some embodiments. The ring layer 380 surrounds the heat conductive layer 370 and the sealant 360, in accordance with some embodiments. The ring layer 380 is made of a polymer material, in accordance with some embodiments.

FIG. 1I-1 is a top view of the chip package structure of FIG. 1I, in accordance with some embodiments. As shown in FIGS. 1I and 1I-1, a heat sink 390 is bonded to the chip package 200 through the sealant 360, the heat conductive layer 370, and the ring layer 380, in accordance with some embodiments.

The heat sink 390 covers the chips 110 and the chip packages 180, in accordance with some embodiments. The heat sink 390 has a central portion 392 and peripheral portions 394, in accordance with some embodiments. The central portion 392 is also referred to as a liquid cooling portion, in accordance with some embodiments. The peripheral portions 394 are also referred to as air cooling portions, in accordance with some embodiments.

The central portion 392 is between the peripheral portions 394, in accordance with some embodiments. The central portion 392 covers the chips 110, in accordance with some embodiments. The peripheral portions 394 cover the chip packages 180, in accordance with some embodiments. The central portion 392 has liquid inlet channels C1 and liquid outlet channels C2, in accordance with some embodiments.

The liquid inlet channel C1 has an L-like shape, in accordance with some embodiments. The liquid outlet channel C2 has an L-like shape, in accordance with some embodiments. The liquid inlet channels C1 and the liquid outlet channels C2 pass through the central portion 392, in accordance with some embodiments. In some embodiments, one of the liquid inlet channels C1 and one of the liquid outlet channels C2 are over one of the chips 110.

As shown in FIG. 1I, the chip 110 has a central portion 110c and peripheral portions 110p1 and 110p2, in accordance with some embodiments. The central portion 110c is between the peripheral portions 110p1 and 110p2, in accordance with some embodiments. The liquid inlet channel C1 and the liquid outlet channel C2 are over the peripheral portions 110p1 and 110p2 respectively, in accordance with some embodiments.

The liquid inlet channel C1 and the liquid outlet channel C2 connect the recess 111a of the semiconductor substrate 111 of the chip 110 thereunder, in accordance with some embodiments. The liquid inlet channel C1 and the liquid outlet channel C2 connect the gaps G1 between the pillars 111b and 111c and the peripheral ring portion 111d of the semiconductor substrate 111 of the chip 110 thereunder, in accordance with some embodiments.

Over one of the chips 110, the cooling liquid (not shown) flows along the path P1 and therefore sequentially passes through the liquid inlet channel C1, the recess 111a in the semiconductor substrate 111 of the chip 110 (or the gaps G1 between the pillars 111b and 111c and the peripheral ring portion 111d), and the liquid outlet channel C2, in accordance with some embodiments.

FIG. 1I-2 is a top view of a first region R1 of the chip package structure of FIG. 1I-1, in accordance with some embodiments. As shown in FIGS. 1I, 1I-1, and 1I-2, when the cooling liquid flows in the recess 111a of the semiconductor substrate 111 of the chip 110 (the left one) between the liquid inlet channel C1 and the liquid outlet channel C2, the cooling liquid flows in the flow direction V1, in accordance with some embodiments.

In the chip 110 (the left one), a direction V111b1 from the wide rounded end E2 to the narrow rounded end E1 of the pillar 111b is parallel to the flow direction V1 of the cooling liquid flowing in the recess 111a (or the gaps G1), which can reduce the flow resistance of the cooling liquid flowing in the recess 111a, in accordance with some embodiments.

The major axis A111b1 of the pillar 111b is parallel to the flow direction V1 of the cooling liquid flowing in the recess 111a between the liquid inlet channel C1 and the liquid outlet channel C2, in accordance with some embodiments. The flow direction V1 is parallel to a direction V12 from the liquid inlet channel C1 to the liquid outlet channel C2, in accordance with some embodiments. The major axis A111b of the pillar 111b is parallel to the direction V12 from the liquid inlet channel C1 to the liquid outlet channel C2, in accordance with some embodiments.

FIG. 1I-3 is a top view of a second region R2 of the chip package structure of FIG. 1I-1, in accordance with some embodiments. As shown in FIGS. 1I, 1I-1, and 1I-3, when the cooling liquid flows in the recess 111a of the semiconductor substrate 111 of the chip 110 (the right one) between the liquid inlet channel C1 and the liquid outlet channel C2, the cooling liquid flows in the flow direction V2, in accordance with some embodiments.

In the chip 110 (the right one), a direction V111b2 from the wide rounded end E2 to the narrow rounded end E1 of the pillar 111b is parallel to the flow direction V2 of the cooling liquid flowing in the recess 111a (or the gaps G1), which can reduce the flow resistance of the cooling liquid flowing in the recess 111a, in accordance with some embodiments.

The major axis A111b2 of the pillar 111b is parallel to the flow direction V2 of the cooling liquid flowing in the recess 111a between the liquid inlet channel C1 and the liquid outlet channel C2, in accordance with some embodiments. The flow direction V2 is parallel to a direction V12′ from the liquid inlet channel C1 to the liquid outlet channel C2, in accordance with some embodiments. The major axis A111b2 of the pillar 111b is parallel to the direction V12′ from the liquid inlet channel C1 to the liquid outlet channel C2, in accordance with some embodiments.

Each peripheral portion 394 has a bottom plate 394a and fins 394b over the bottom plate 394a, in accordance with some embodiments. The fins 394b are spaced apart from each other by gaps G2, in accordance with some embodiments. The fins 394b are over the chip packages 180, in accordance with some embodiments.

The fins 394b extend in the direction V0 away from the redistribution substrate 170, in accordance with some embodiments. The pillars 111b and 111c and the peripheral ring portion 111d of the semiconductor substrate 111 also extend in the direction V0, in accordance with some embodiments.

The sealant 360 is between the heat sink 390 and the chip 110, in accordance with some embodiments. The sealant 360 is between the heat sink 390 and the underfill layer 190, in accordance with some embodiments. The sealant 360 is used to isolate the cooling liquids over different chips 110 from each other, in accordance with some embodiments. Therefore, the flow rate or composition of the cooling liquids on different chips 110 can be individually adjusted as needed, in accordance with some embodiments.

The heat conductive layer 370 is between the chip package 180 and the bottom plate 394a of the peripheral portions 394 of the heat sink 390, in accordance with some embodiments. The ring layer 380 is connected between the molding layer 210 and the bottom plate 394a of the peripheral portions 394 of the heat sink 390, in accordance with some embodiments.

The heat sink 390 is made of a heat conductive material such as metal (e.g., Al) or alloys thereof, in accordance with some embodiments. In this step, a chip package structure 300 is substantially formed, in accordance with some embodiments.

Since the application forms the recess 111a in the back surface S2 of the semiconductor substrate 111 of the chip 110, the cooling liquid flowing in the recess 111a can be close to the hot spots (e.g., the devices formed at the front surface S1 of the semiconductor substrate 111 of the chip 110), which can improve the heat dissipation efficiency, in accordance with some embodiments.

The heat sink 390 has a liquid cooling portion (i.e., the central portion 392) and air cooling portions (i.e., the peripheral portions 394) to meet different requirements of different devices (e.g., the chip 110 and the chip package 180), in accordance with some embodiments.

For example, the chip 110 may generate more heat than the chip package 180, and the liquid cooling portion may has a higher heat dissipation efficiency than the air cooling portion. Therefore, the liquid cooling portion and the air cooling portions are respectively disposed over the chip 110 and the chip packages 180 to maintain the operating temperatures of the chip 110 and the chip packages 180 within an acceptable range, in accordance with some embodiments.

FIG. 2A is a cross-sectional view of a chip package structure 400, in accordance with some embodiments. FIG. 2B is a top view of the chip package structure 400 of FIG. 2A, in accordance with some embodiments.

As shown in FIGS. 2A and 2B, the chip package structure 400 is similar to the chip package structure 300 of FIGS. 1I and 1I-1, except that the liquid inlet channel C1 of the chip package structure 400 has an I-like shape, and the liquid outlet channel C2 of the chip package structure 400 has an I-like shape, in accordance with some embodiments.

Processes and materials for forming the chip package structure 400 may be similar to, or the same as, those for forming the chip package structure 300 described above. Elements designated by the same or similar reference numbers as those in FIGS. 1A to 2B have the same or similar structures and the materials. Therefore, the detailed descriptions thereof will not be repeated herein.

In accordance with some embodiments, chip package structures and methods for forming the same are provided. The methods (for forming the chip package structure) form a recess in a back surface of a semiconductor substrate of a chip. Therefore, a cooling liquid can flow in the recess to be close to the hot spots (e.g., devices formed at a front surface of the semiconductor substrate of the chip), which can improve the heat dissipation efficiency.

In accordance with some embodiments, a method for forming a chip package structure is provided. The method includes providing a chip having a semiconductor substrate and a conductive bump. The semiconductor substrate has a front surface and a back surface, and the conductive bump is over the front surface. The method includes partially removing the semiconductor substrate from the back surface to form a recess in the semiconductor substrate. After the semiconductor substrate is partially removed, the semiconductor substrate has a first pillar and a second pillar protruding from a bottom surface of the recess. The method includes bonding a heat sink to the chip. The heat sink has a first channel and a second channel, and the first channel and the second channel pass through the heat sink and connect the recess.

In accordance with some embodiments, a method for forming a chip package structure is provided. The method includes bonding a chip to a redistribution substrate. The chip has a semiconductor substrate, the semiconductor substrate has a first pillar and a second pillar extending in a direction away from the redistribution substrate, and the first pillar is spaced apart from the second pillar by a gap. The method includes bonding a heat sink to the chip. The heat sink has a first channel and a second channel, and the first channel and the second channel pass through the heat sink and connect the gap between the first pillar and the second pillar.

In accordance with some embodiments, a chip package structure is provided. The chip package structure includes a redistribution substrate. The chip package structure includes a chip over the redistribution substrate. The chip has a semiconductor substrate, the semiconductor substrate has a first pillar and a second pillar extending in a direction away from the redistribution substrate, and the first pillar is spaced apart from the second pillar by a gap. The chip package structure includes a heat sink over the chip and having a first channel and a second channel. The first channel and the second channel pass through the heat sink and connect the gap between the first pillar and the second pillar.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a chip package structure, comprising:
providing a chip having a semiconductor substrate and a conductive bump, wherein the semiconductor substrate has a front surface and a back surface, and the conductive bump is over the front surface;
partially removing the semiconductor substrate from the back surface to form a recess in the semiconductor substrate, wherein after the semiconductor substrate is partially removed, the semiconductor substrate has a first pillar and a second pillar protruding from a bottom surface of the recess; and
bonding a heat sink to the chip, wherein the heat sink has a first channel and a second channel, and the first channel and the second channel pass through the heat sink and connect the recess.

2. The method for forming the chip package structure as claimed in claim 1, further comprising:
forming a sealant over a peripheral ring portion of the semiconductor substrate after the semiconductor substrate is partially removed and before the heat sink is bonded to the chip, wherein the peripheral ring portion surrounds the recess, and the sealant is between the heat sink and the chip.

3. The method for forming the chip package structure as claimed in claim 1, further comprising:
bonding the chip to a redistribution substrate before the heat sink is bonded to the chip.

4. The method for forming the chip package structure as claimed in claim 3, further comprising:
bonding a chip package to the redistribution substrate before the heat sink is bonded to the chip, wherein the heat sink covers the chip and the chip package.

5. The method for forming the chip package structure as claimed in claim 4, wherein the heat sink has a first portion and a second portion, the first portion covers the chip, the second portion covers the chip package, the first channel and the second channel pass through the first portion, and the second portion has a bottom plate and a fin over the bottom plate.

6. The method for forming the chip package structure as claimed in claim 5, further comprising:
forming a heat conductive layer over the chip package before the heat sink is bonded to the chip, wherein the heat conductive layer is between the chip package and the bottom plate of the second portion of the heat sink.

7. The method for forming the chip package structure as claimed in claim 6, further comprising:
forming a molding layer over the redistribution substrate and surrounding the chip package and the chip before the heat sink is bonded to the chip; and
forming a ring layer over the molding layer and surrounding the heat conductive layer.

8. The method for forming the chip package structure as claimed in claim 7, wherein the ring layer is connected between the molding layer and the bottom plate of the second portion of the heat sink.

9. The method for forming the chip package structure as claimed in claim 3, further comprising:
bonding the redistribution substrate to a wiring substrate before the heat sink is bonded to the chip; and
bonding a ring structure to the wiring substrate, wherein the ring structure surrounds the chip and the redistribution substrate.

10. The method for forming the chip package structure as claimed in claim 1, wherein the first pillar has an egg-like shape.

11. A method for forming a chip package structure, comprising:
bonding a chip to a redistribution substrate, wherein the chip has a semiconductor substrate, the semiconductor substrate has a first pillar and a second pillar extending in a direction away from the redistribution substrate, and the first pillar is spaced apart from the second pillar by a gap; and
bonding a heat sink to the chip, wherein the heat sink has a first channel and a second channel, and the first channel and the second channel pass through the heat sink and connect the gap between the first pillar and the second pillar.

12. The method for forming the chip package structure as claimed in claim 11, further comprising:
bonding a chip package to the redistribution substrate before the heat sink is bonded to the chip, wherein the heat sink covers the chip and the chip package, and the heat sink has a fin over the chip package and extending in the direction away from the redistribution substrate.

13. The method for forming the chip package structure as claimed in claim 12, further comprising:
forming an underfill layer between the chip, the chip package, and the redistribution substrate before the heat sink is bonded to the chip.

14. The method for forming the chip package structure as claimed in claim 13, further comprising:
forming a sealant over the underfill layer before the heat sink is bonded to the chip, wherein the sealant is between the heat sink and the underfill layer.

15. The method for forming the chip package structure as claimed in claim 12, wherein a first top surface of the first pillar, a second top surface of the second pillar, and a third top surface of the chip package are substantially level with each other.

16. A chip package structure, comprising:
a redistribution substrate;
a chip over the redistribution substrate, wherein the chip has a semiconductor substrate, the semiconductor substrate has a first pillar and a second pillar extending in a direction away from the redistribution substrate, and the first pillar is spaced apart from the second pillar by a gap; and
a heat sink over the chip and having a first channel and a second channel, wherein the first channel and the second channel pass through the heat sink and connect the gap between the first pillar and the second pillar.

17. The chip package structure as claimed in claim 16, further comprising:
a sealant between the chip and the heat sink and surrounding the first pillar and the second pillar.

18. The chip package structure as claimed in claim 16, further comprising:
a chip package over the redistribution substrate, wherein the heat sink covers the chip and the chip package, and the heat sink has a fin over the chip package and extending in the direction away from the redistribution substrate.

19. The chip package structure as claimed in claim 18, further comprising:
a heat conductive layer between the chip package and the heat sink.

20. The chip package structure as claimed in claim 19, further comprising:
a molding layer over the redistribution substrate and surrounding the chip package and the chip; and
a ring layer between the molding layer and the heat sink and surrounding the heat conductive layer.
